(19) United States
(12) Patent Application Publication
(10) Pub. No.: US 2012/0241741 A1
(43) Pub. Date: Sep. 27, 2012

(54) SILICON CARBIDE SUBSTRATE

(75) Inventors: Hiroki INOUE, Itami-shi (JP); Shin Harada, Osaka-shi (JP); Tsutomu Hori, Itami-shi (JP); Shinsuke Fujiwara, Itami-shi (JP)

(73) Assignee: SUMITOMO ELECTRIC INDUSTRIES, LTD., Osaka-shi (JP)

(21) Appl. No.: 13/420,117

(22) Filed: Mar. 14, 2012

Related U.S. Application Data
(60) Provisional application No. 61/467,565, filed on Mar. 25, 2011.

(30) Foreign Application Priority Data
Mar. 25, 2011 (JP) 2011-066916

(51) Int. Cl. H01L 29/04; H01L 29/24

(52) U.S. Cl. 257/51; 257/E29.003; 257/E29.104

(57) ABSTRACT

A first single crystal substrate has a first side surface and it is composed of silicon carbide. A second single crystal substrate has a second side surface opposed to the first side surface and it is composed of silicon carbide. A bonding portion connects the first and second side surfaces to each other between the first and second side surfaces, and it is composed of silicon carbide. At least a part of the bonding portion has polycrystalline structure. Thus, a large-sized silicon carbide substrate allowing manufacturing of a semiconductor device with high yield can be provided.

### BACKGROUND OF THE INVENTION

1. Field of the Invention

The present invention relates to a silicon carbide substrate.

2. Description of the Background Art

In recent years, silicon carbide substrates have increasingly been adopted as semiconductor substrates for use in manufacturing semiconductor devices. Silicon carbide (SiC) is greater in band gap than silicon (Si), which has more commonly been used. Hence, a semiconductor device including a silicon carbide substrate advantageously has a high reverse breakdown voltage and low on-resistance, or properties less likely to deteriorate in a high temperature environment.

In order to efficiently manufacture a semiconductor device by using a semiconductor substrate, a substrate should be large in size to some extent. According to U.S. Pat. No. 7,314,520 (Patent Literature 1), a silicon carbide substrate of 76 mm (3 inches) or greater can be manufactured.

Industrially, it has been difficult to manufacture a silicon carbide substrate having a size of approximately 100 mm or greater. Accordingly, it has been difficult to efficiently manufacture semiconductor devices using large substrates. This disadvantage becomes particularly serious in the case of using a property of a plane other than a (0001) plane in SiC of hexagonal system, which will be described below.

A silicon carbide substrate having fewer defects is usually manufactured by cutting a silicon carbide ingot obtained by growth on the (0001) plane, which is less likely to cause stacking faults. Hence, a silicon carbide substrate having a plane orientation other than the (0001) plane is obtained by cutting the ingot not in parallel to its grown surface. Therefore, it has been difficult to secure a sufficient size of the substrate or most of the ingot cannot effectively be used. For this reason, it is particularly difficult to efficiently manufacture a semiconductor device that makes use of a plane other than the (0001) plane of SiC.

Instead of increasing the size of a silicon carbide substrate with such difficulty, it is considered to use a silicon carbide substrate having a supporting portion and a plurality of single crystal substrates of high quality arranged thereon. Since the supporting portion does not have to have such high quality, it is relatively easy to prepare a large supporting portion. Therefore, a silicon carbide substrate having a necessary size can be obtained by increasing the number of single crystal substrates placed on this large supporting portion.

In this silicon carbide substrate, however, gaps are inevitably formed between adjacent single crystal substrates. In a gap, foreign matters are likely to accumulate during a process of manufacturing a semiconductor device using this silicon carbide substrate. An exemplary foreign matter is a cleaning liquid or a polishing agent used in the process of manufacturing a semiconductor device or dust in an atmosphere. It is difficult to completely remove foreign matters by cleaning, because they are present in a small gap. Therefore, the foreign matters result in lowering in manufacturing yield, which leads to lower efficiency in manufacturing semiconductor devices.

### SUMMARY OF THE INVENTION

The present invention was made in view of the above-described problems and its object is to provide a large-sized silicon carbide substrate allowing manufacturing of semiconductor devices with high yield.

A silicon carbide substrate according to the present invention has first and second single crystal substrates and a bonding portion. The first single crystal substrate has a first side surface and it is composed of silicon carbide. The second single crystal substrate has a second side surface opposed to the first side surface and it is composed of silicon carbide. The bonding portion connects the first and second side surfaces to each other between the first and second side surfaces and it is composed of silicon carbide. At least a part of the bonding portion has polycrystalline structure.

According to this silicon carbide substrate, since at least a part of a gap between the first and second single crystal substrates, that is, between the first and second side surfaces, is buried with the bonding portion, foreign matters can be suppressed from accumulating in this gap in manufacturing of a semiconductor device with the silicon carbide substrate. Since yield can thus be prevented from lowering due to these foreign matters, semiconductor devices can be manufactured with high yield. In addition, since at least a part of the bonding portion has polycrystalline structure, stress at the bonding portion is likely to be mitigated as compared with a case where the bonding portion has single crystal structure in its entirety. Thus, warpage of the silicon carbide substrate originating from stress can be suppressed.

The first and second single crystal substrates may have first and second back surfaces, respectively. The silicon carbide substrate may further have a supporting portion bonded to each of the first and second back surfaces. Thus, as compared with a case where the first and second single crystal substrates are coupled to each other only with the bonding portion, the first and second single crystal substrates can more securely be coupled to each other.

The first and second single crystal substrates may have first and second front surfaces, respectively. The bonding portion may be formed to linearly extend between the first and second front surfaces in a plan view. A length of a portion of the bonding portion having polycrystalline structure in a direction of linear extension may be not less than 1% and not more than 100% of the entire length of the bonding portion. As this percentage is not lower than 1%, stress described above is more reliably mitigated.

The length of the portion of the bonding portion having polycrystalline structure in the direction of linear extension may be not less than 10% of the entire length of the bonding portion. Thus, stress described above is more sufficiently mitigated.

A ratio of a maximum length in the plan view of the silicon carbide substrate with respect to a thickness of the silicon carbide substrate may be not lower than 50 and not higher than 500. As this ratio is not lower than 50, a size of the silicon carbide substrate in a plan view can sufficiently be secured. In addition, as this ratio is not higher than 500, warpage of the silicon carbide substrate can further be suppressed.

A maximum length in a plan view of the silicon carbide substrate may be not smaller than 100 mm. Thus, a silicon carbide substrate having a sufficient size is obtained.

As apparent from the description above, the present invention can provide a silicon carbide substrate having a large size, being less in warpage, and allowing manufacturing of semiconductor devices with high yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a construction of a silicon carbide substrate in a first embodiment of the present invention.

FIG. 2 is a schematic cross-sectional view along the line II-II in FIG. 1.

FIG. 3A is a partial cross-sectional view of the silicon carbide substrate in FIG. 1, showing a region including a bonding portion having single crystal structure.

FIG. 3B is a partial cross-sectional view of the silicon carbide substrate in FIG. 1, showing a region including a bonding portion having polycrystalline structure.

FIG. 4 is a plan view schematically showing a first step of a method for manufacturing a silicon carbide substrate in the first embodiment of the present invention.

FIG. 5 is a schematic cross-sectional view along the line V-V in FIG. 4.

FIG. 6 is a cross-sectional view schematically showing a second step of the method for manufacturing a silicon carbide substrate in the first embodiment of the present invention.

FIG. 7 is a partial cross-sectional view schematically showing a third step of the method for manufacturing a silicon carbide substrate in the first embodiment of the present invention.

FIG. 8A is a partial cross-sectional view schematically showing a fourth step of the method for manufacturing a silicon carbide substrate in the first embodiment of the present invention, showing a region where a bonding portion having single crystal structure is formed.

FIG. 8B is a partial cross-sectional view schematically showing the fourth step of the method for manufacturing a silicon carbide substrate in the first embodiment of the present invention, showing a region where a bonding portion having polycrystalline structure is formed.

FIG. 9 is a graph showing one example of relation between a ratio of polycrystalline structure in the bonding portion and warpage of the silicon carbide substrate.

FIG. 10 is a graph showing one example of relation between a ratio of a maximum length in a plan view of the silicon carbide substrate with respect to a thickness of the silicon carbide substrate and warpage of the silicon carbide substrate.

FIG. 11 is a cross-sectional view schematically showing a first step of a method for manufacturing a silicon carbide substrate in a second embodiment of the present invention.

FIG. 12 is a cross-sectional view schematically showing a second step of the method for manufacturing a silicon carbide substrate in the second embodiment of the present invention.

FIG. 13 is a cross-sectional view schematically showing a third step of the method for manufacturing a silicon carbide substrate in the second embodiment of the present invention.

FIG. 14 is a cross-sectional view schematically showing one step of a method for manufacturing a silicon carbide substrate in a first variation of the second embodiment of the present invention.

FIG. 15 is a cross-sectional view schematically showing one step of a method for manufacturing a silicon carbide substrate in a second variation of the second embodiment of the present invention.

FIG. 16 is a cross-sectional view schematically showing one step of a method for manufacturing a silicon carbide substrate in a third variation of the second embodiment of the present invention.

FIG. 17 is a cross-sectional view schematically showing one step of a method for manufacturing a silicon carbide substrate in a third embodiment of the present invention.

FIG. 18 is a cross-sectional view schematically showing a first step of a method for manufacturing a silicon carbide substrate in a variation of the third embodiment of the present invention.

FIG. 19 is a cross-sectional view schematically showing a second step of the method for manufacturing a silicon carbide substrate in the variation of the third embodiment of the present invention.

FIG. 20 is a cross-sectional view schematically showing a third step of the method for manufacturing a silicon carbide substrate in the variation of the third embodiment of the present invention.

FIG. 21 is a partial cross-sectional view schematically showing a construction of a semiconductor device in a fourth embodiment of the present invention.

FIG. 22 is a schematic flowchart of a method for manufacturing a semiconductor device in the fourth embodiment of the present invention.

FIG. 23 is a partial cross-sectional view schematically showing a first step of the method for manufacturing a semiconductor device in the fourth embodiment of the present invention.

FIG. 24 is a partial cross-sectional view schematically showing a second step of the method for manufacturing a semiconductor device in the fourth embodiment of the present invention.

FIG. 25 is a partial cross-sectional view schematically showing a third step of the method for manufacturing a semiconductor device in the fourth embodiment of the present invention.

FIG. 26 is a partial cross-sectional view schematically showing a fourth step of the method for manufacturing a semiconductor device in the fourth embodiment of the present invention.

### DESCRIPTION OF THE PREFERRED EMBODIMENTS

An embodiment of the present invention will be described hereinafter with reference to the drawings.

### First Embodiment

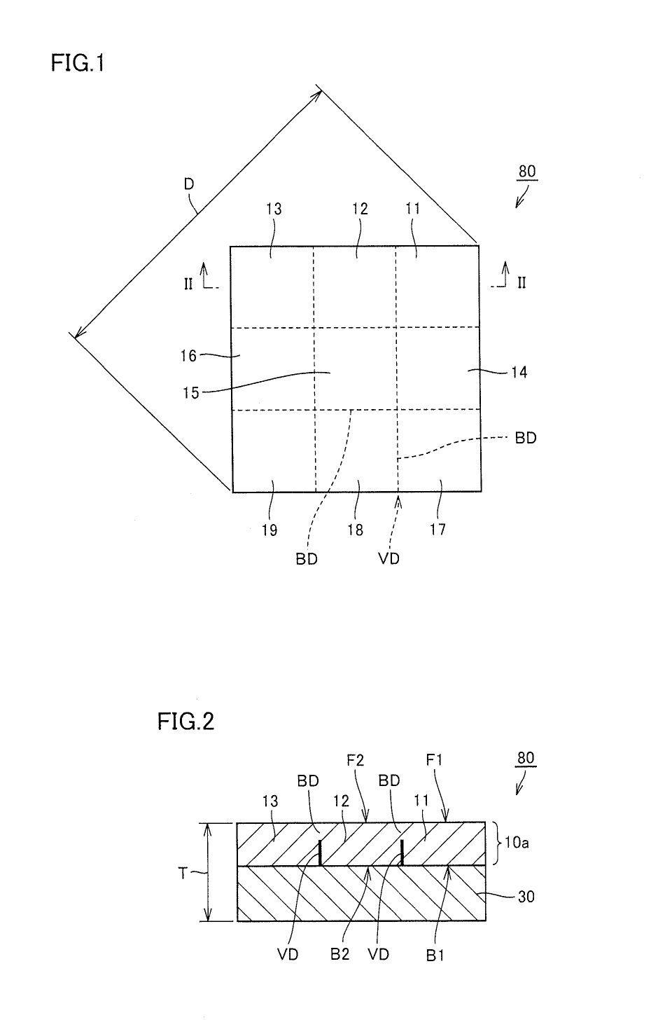

Referring to FIGS. 1 and 2, a silicon carbide substrate 80 in the present embodiment has a supporting portion 30, a supported portion 10a supported by supporting portion 30, and a bonding portion BD. Supported portion 10a has single crystal substrates 11 to 19 composed of silicon carbide. Each of single crystal substrates 11 to 19 has a back surface and a front surface. For example, single crystal substrate 11 (a first single crystal substrate) has a back surface B1 (a first back surface) and a front surface F1 (a first front surface), while single crystal substrate 12 (a second single crystal substrate) has a back surface B2 (a second back surface) and a front surface F2 (a second front surface). Supporting portion 30 is bonded to the back surface of each of single crystal substrates 11 to 19.

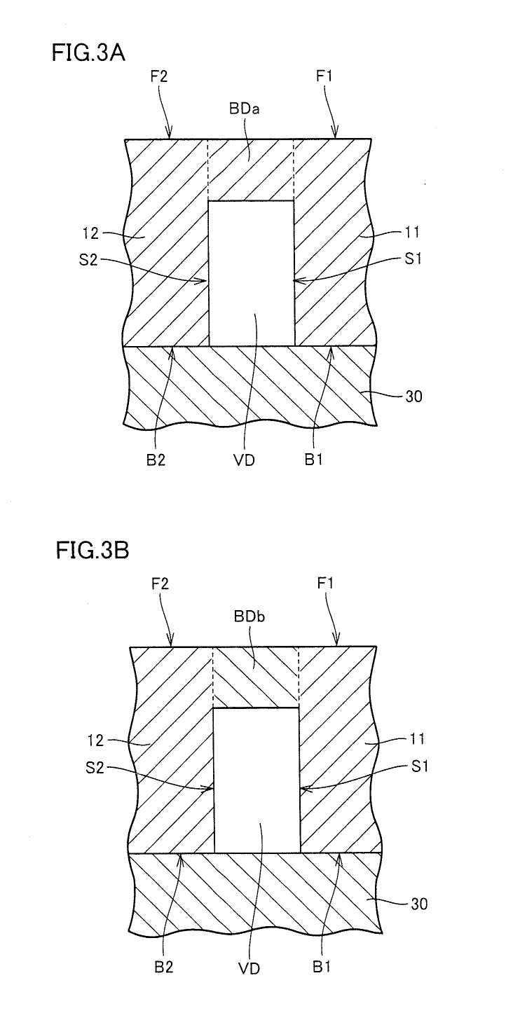

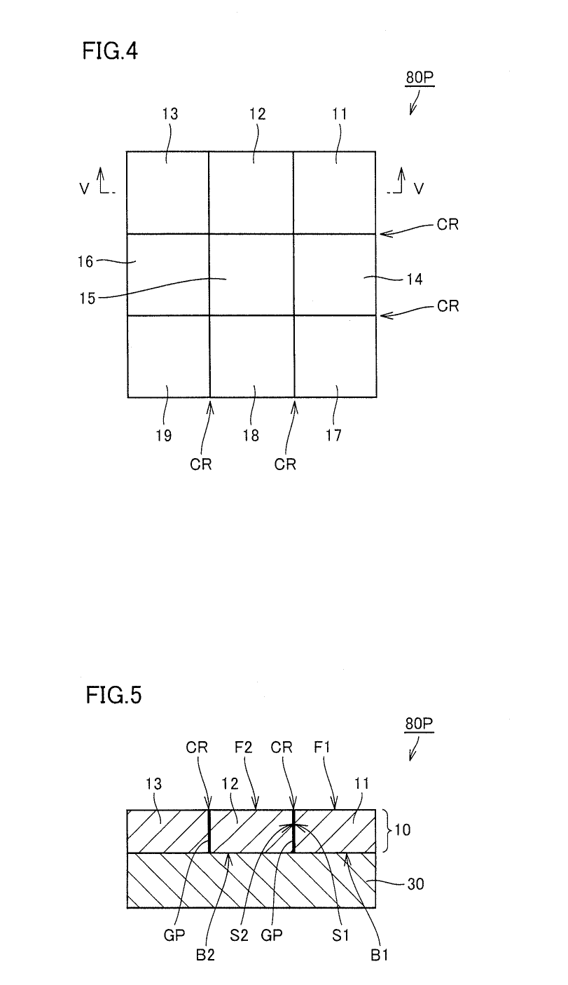

Referring to FIGS. 3A, 3B, and 4, each of single crystal substrates 11 to 19 has a side surface. For example, single crystal substrate 11 has a side surface S1 (a first side surface), and single crystal substrate 12 has a side surface S2 (a second side surface) opposed to side surface S1. A gap VD is present between the side surfaces opposed to each other.

Bonding portion BD connects to each other, the side surfaces opposed to each other between these side surfaces. For example, side surfaces S1 and S2 are connected to each other between side surfaces S1 and S2. A front surface side (an upper side in FIG. 2) of gap VD is closed by bonding portion BD. Bonding portion BD includes, for example, a portion located between front surfaces F1 and F2, and hence front surfaces F1 and F2 are smoothly connected to each other.

Bonding portion BD has a polycrystalline portion BDb (FIG. 3B) having polycrystalline structure of silicon carbide. Alternatively, bonding portion BD may have a single crystal portion BDa (FIG. 3A) having single crystal structure of silicon carbide.

In a plan view (FIG. 1), bonding portion BD may be formed to linearly extend between the front surfaces of the single crystal substrates adjacent to each other among single crystal substrates 11 to 19. For example, bonding portion BD may be formed to linearly extend between front surface F1 of single crystal substrate 11 and front surface F2 of single crystal substrate 12. Preferably, the total length of polycrystalline portion BDb in a direction of linear extension of bonding portion BD is not less than 1% and not more than 100% of the entire length of bonding portion BD. Further preferably, this percentage is not lower than 10%.

Preferably, a ratio of a maximum length D (FIG. 1) in the plan view (FIG. 1) of silicon carbide substrate 80 with respect to a thickness T (FIG. 2) of silicon carbide substrate 80 is not lower than 50 and not higher than 500. Further preferably, maximum length D is not smaller than 100 mm.

Supporting portion 30 is preferably formed of a material capable of withstanding a temperature of 1800° C. or higher, such as silicon carbide, carbon, or a refractory metal. An exemplary refractory metal is molybdenum, tantalum, tungsten, niobium, iridium, ruthenium, or zirconium. When silicon carbide is employed as the material for supporting portion 30 from among the above, supporting portion 30 has physical properties closer to those of single crystal substrates 11 to 19.

Though supporting portion 30 is provided in silicon carbide substrate 80 in the present embodiment, such a construction not including supporting portion 30 may be employed. This construction is obtained, for example, by removing supporting portion 30 of silicon carbide substrate 80 (FIG. 2) through polishing. Further, though a square shape is shown as a shape of silicon carbide substrate 80 in the plan view in FIG. 1, the shape is not limited to square and it may be, for example, circular. In a case where this shape is circular, a diameter of the circular shape represents maximum length D (FIG. 1).

A method for manufacturing silicon carbide substrate 80 in the present embodiment will now be described. For simplification of description below, only single crystal substrates 11 and 12 among single crystal substrates 11 to 19 may be mentioned, however, single crystal substrates 13 to 19 are also handled similarly to single crystal substrates 11 and 12.

Referring to FIGS. 4 and 5, a combined substrate 80P is prepared. Combined substrate 80P has supporting portion 30 and a single crystal substrate group 10. Single crystal substrate group 10 includes single crystal substrates 11 and 12. Each of back surface B1 of single crystal substrate 11 and back surface B2 of single crystal substrate 12 is bonded to supporting portion 30. A gap GP is formed between side surface S1 of single crystal substrate 11 and side surface S2 of single crystal substrate 12. Gap GP has an opening CR between front surface F1 of single crystal substrate 11 and front surface F2 of single crystal substrate 12.

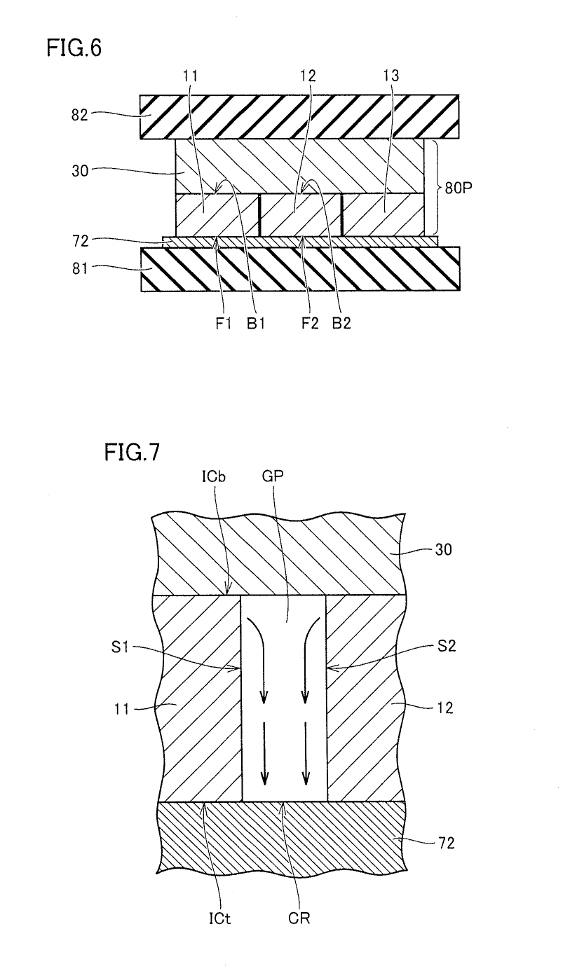

Referring to FIG. 6, heating elements 81 and 82 are prepared. Each of heating elements 81 and 82 is capable of generating heat, such as an element generating heat by being heated by induction heating or a heat generating element of a resistance heating type. A graphite sheet 72 (a closing portion) having flexibility is disposed on heating element 81. In addition, combined substrate 80P is placed on graphite sheet 72 such that front surfaces F1 and F2 face graphite sheet 72. Further, heating element 82 is placed on supporting portion 30.

Then, combined substrate 80P is heated by heating elements 81 and 82. Heating is performed to produce a temperature gradient in a direction of thickness of single crystal substrate group 10 such that a temperature on a side ICt of single crystal substrate group 10 (FIG. 5) facing graphite sheet 72 is lower than a temperature on a side ICb of single crystal substrate group 10 facing supporting portion 30. Such a temperature gradient is attained, for example, by performing heating such that graphite sheet 72 is lower in temperature than supporting portion 30.

Referring to FIG. 7, as indicated by an arrow in the figure, this heating causes mass transfer involved with sublimation from a relatively high-temperature region close to side ICb to a relatively low-temperature region close to side ICt, in the surfaces of single crystal substrates 11 and 12 in closed gap GP, that is, side surfaces S1 and S2. As a result of this mass transfer, in gap GP closed by graphite sheet 72, sublimates from side surfaces S1 and S2 are deposited on graphite sheet 72.

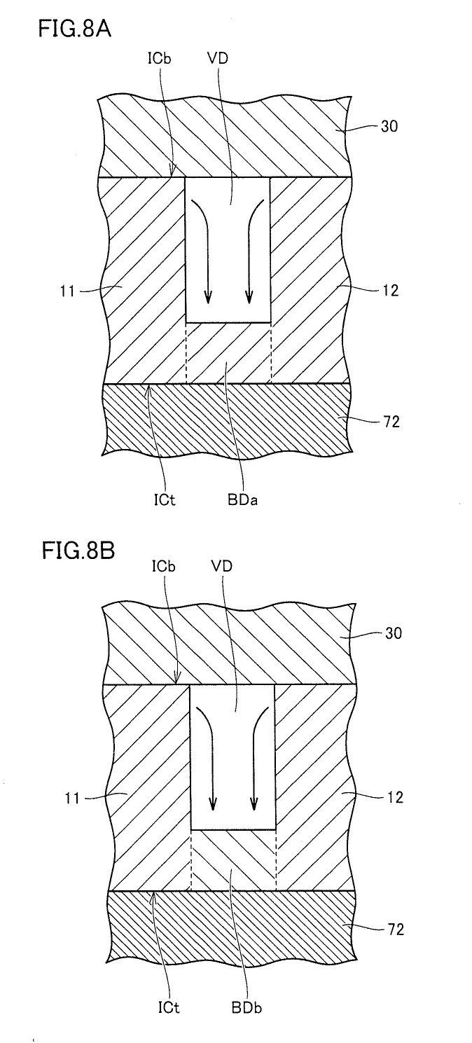

Further, referring to FIGS. 8A and 8B, as a result of deposition above, bonding portion BD connecting side surfaces S1 and S2 to each other to thereby close opening CR of gap GP (FIG. 7) is formed. Consequently, gap GP (FIG. 7) is formed into gap VD closed by bonding portion BD. A portion of bonding portion BD that has grown under the influence of side surfaces S1 and S2 becomes single crystal portion BDa (FIG. 8A) as influenced by single crystal structure of single crystal substrates 11 and 12. On the other hand, a portion of bonding portion BD that has grown under the influence of graphite sheet 72 becomes polycrystalline portion BDb (FIG. 8B). A ratio of a portion of bonding portion BD that grows under the influence of graphite sheet 72 increases, for example, by increasing an interval between side surfaces S1 and S2 (FIG. 7).

Silicon carbide substrate 80 (FIG. 2) is obtained as above.

It should be noted that an experiment was conducted to review temperatures for heating combined substrate 80P. It was found that, at 1600° C., bonding portion BD was not sufficiently foiined, and at 3000° C., single crystal substrates 11, 12 were damaged. These problems, however, were not seen at 1800° C., 2000° C., and 2500° C. In addition, with a heating temperature being fixed to 2000° C., atmospheric pressures during heating above were reviewed. As a result, at 100 kPa, bonding portion BD was not formed, and at 50 kPa, bonding portion BD was less likely to be foi med. These problems, however, were not seen at 10 kPa, 100 Pa, 1 Pa, 0.1 Pa, and 0.0001 Pa.

According to the present embodiment, as shown in FIG. 2, single crystal substrates 11 and 12 are combined as one silicon carbide substrate 80 through supporting portion 30. Silicon carbide substrate 80 includes both front surfaces F1 and F2 of the respective single crystal substrates as its substrate surface on which a semiconductor device such as a transistor is to be formed. In other words, silicon carbide substrate 80 has a substrate surface larger than in the case where any of single crystal substrates 11 and 12 is used alone. For example, maximum length D in the plan view (FIG. 1) of silicon carbide substrate 80 is not smaller than 100 mm. Thus, a semiconductor device can efficiently be manufactured by using silicon carbide substrate 80.

Further, in the process of manufacturing silicon carbide substrate 80, opening CR present between front surfaces F1 and F2 of combined substrate 80P (FIG. 5) is closed by bonding portion BD (FIG. 2). Accordingly, front surfaces F1 and F2 become a surface smoothly connected to each other. As such, in the process of manufacturing a semiconductor device using silicon carbide substrate 80, foreign matters, which would cause lowering in yield, are less likely to accumulate between front surfaces F1 and F2. Thus, use of silicon carbide substrate 80 allows manufacturing of semiconductor devices with high yield.

In addition, since bonding portion BD includes polycrystalline portion BDb (FIG. 3B), mitigation of stress in bonding portion BD is more likely than in a case where bonding portion BD is formed from single crystal portion BDa (FIG. 3A) in its entirety. Thus, warpage of silicon carbide substrate 80 originating from stress can be suppressed. In the present embodiment, bonding portion BD is formed to linearly extend between front surfaces F1 and F2 in the plan view (FIG. 1). In a case where a length of a portion of bonding portion BD having polycrystalline structure in a direction of linear extension is not less than 1% and not more than 100% of the entire length of bonding portion BD, stress described above is further reliably mitigated. When this percentage is not lower than 10%, stress described above is more sufficiently mitigated.

Moreover, as supporting portion 30 bonded to each of single crystal substrates 11 and 12 is provided, single crystal substrates 11 and 12 can be coupled to each other more securely than in a case where bonding portion BD alone couples single crystal substrates 11 and 12 to each other.

Further, in a case where a ratio of maximum length D (FIG. 1) in the plan view (FIG. 1) of silicon carbide substrate 80 with respect to thickness T (FIG. 2) of silicon carbide substrate 80 is not lower than 50, a size of silicon carbide substrate 80 in the plan view can sufficiently be secured. For example, in a case where D/T is 50, a silicon carbide substrate satisfying T=2 mm and D=100 mm is obtained. Furthermore, as this ratio is not higher than 500, warpage of silicon carbide substrate 80 can further be suppressed.

One example of a function and effect above will be described below.

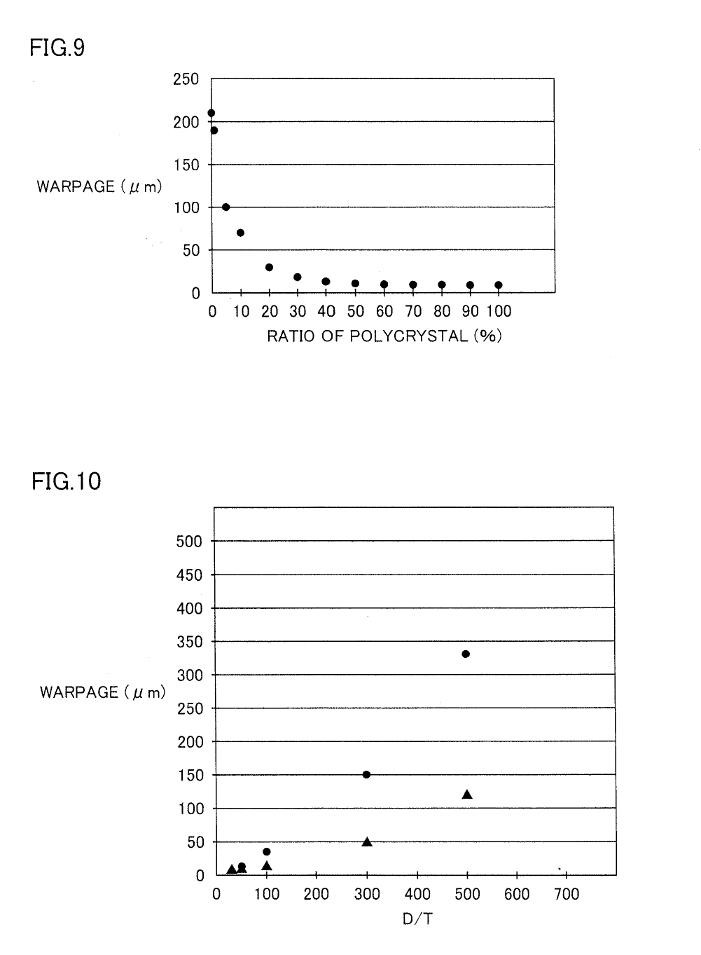

Referring to FIG. 9, one example of relation between a percentage of a length of polycrystalline portion BDb (FIG. 3B) of bonding portion BD with respect to the entire length of bonding portion BD in the direction of linear extension of bonding portion BD between front surfaces F1 and F2 in the plan view (FIG. 1) and warpage of silicon carbide substrate 80 will be described. In a case where this percentage is 0%, warpage was approximately 210 μm, while in a case where this percentage is 1%, warpage was suppressed to approximately 190 μm. In a case where this percentage is 10%, warpage was suppressed to approximately 65 μm.

Referring to FIG. 10, one example of relation between a ratio of maximum length D (FIG. 1) in the plan view (FIG. 1) of silicon carbide substrate 80 with respect to thickness T (FIG. 2) of silicon carbide substrate 80 and warpage of silicon carbide substrate 80 will be described. In the graph in FIG. 10, a circular plot corresponds to a case where the percentage above is 0%, that is, a case where a length of single crystal portion BDa occupies the entire length of bonding portion BD, and a triangular plot corresponds to a case where the percentage above is 10%. Based on this result, it was found that warpage of silicon carbide substrate 80 was suppressed in a case where polycrystalline portion BDb was formed by 10% in terms of length, as compared with a case where bonding portion BD was formed only from single crystal portion BDa. In addition, it was found that warpage was smaller as D/T was smaller, warpage could readily be suppressed when D/T was set, for example, to 500 or smaller, and warpage could be suppressed to 150 μm or smaller when the percentage above was, for example, 10%.

### Second Embodiment

In the present embodiment, a particular case where supporting portion 30 is made of silicon carbide in the method for manufacturing combined substrate 80P (FIGS. 4, 5) used in the first embodiment will be described in detail. For simplification of description below, only single crystal substrates 11 and 12 among single crystal substrates 11 to 19 (FIGS. 4, 5) may be mentioned, however, single crystal substrates 13 to 19 are also handled similarly to single crystal substrates 11 and 12.

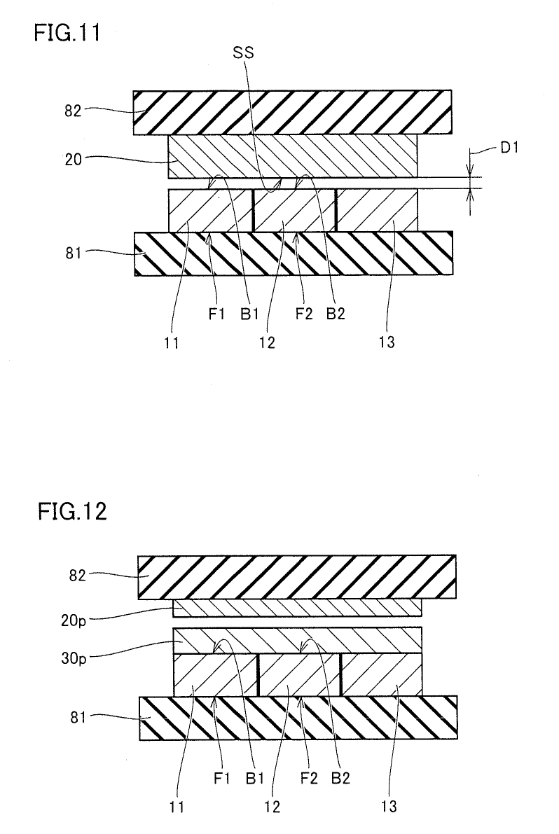

Referring to FIG. 11, single crystal substrates 11 and 12 having single crystal structure are prepared. For example, this step is performed by slicing a silicon carbide ingot grown on the (0001) plane in the hexagonal system. Preferably, back surfaces B1 and B2 have roughness Ra not greater than 100 μm. In addition, preferably a {0001 } plane or a {03-38} plane, more preferably a (000-1) plane or a (03-3-8) plane, is adopted as a crystal plane of the surface of each of single crystal substrates 11 and 12.

Then, single crystal substrates 11 and 12 are arranged on heating member 81 in a processing chamber with each of back surfaces B1 and B2 being exposed in one direction (upward in FIG. 11). Namely, in a plan view, single crystal substrates 11 and 12 are arranged side by side.

Preferably, the arrangement above is such that back surfaces B1 and B2 are flush with each other or front surfaces F1 and F2 are flush with each other.

Then, supporting portion 30 (FIG. 5) connecting back surfaces B1 and B2 to each other is formed in the following manner.

Initially, each of back surfaces B1 and B2 exposed in one direction (upward in FIG. 11) and a surface SS of a solid source material 20 arranged in one direction (upward in FIG. 11) relative to back surfaces B1 and B2 are opposed to each other at a distance D1 from each other. Preferably, an average value of distance D1 is not smaller than 1 μm and not greater than 1 cm.

Solid source material 20 is composed of silicon carbide and is preferably a piece of solid matter of silicon carbide, specifically, an SiC wafer, for example. Solid source material 20 is not particularly limited in terms of crystal structure of SiC. Further preferably, surface SS of solid source material 20 has roughness Ra not greater than 1 mm.

In order to more reliably provide distance D1 (FIG. 11), a spacer 83 (FIG. 14) having a height corresponding to distance D1 may be employed. This method is particularly effective when the average value of distance D1 is approximately 100 μm or greater.

Then, single crystal substrates 11 and 12 are heated by heating member 81 to a prescribed substrate temperature. Solid source material 20 is heated by heating member 82 to a prescribed source material temperature. When solid source material 20 is thus heated to the source material temperature, SiC is sublimated at surface SS of the solid source material to generate a sublimate, i.e., a gas. This gas is supplied onto back surfaces B1 and B2 in one direction (upward in FIG. 11).

Preferably, the substrate temperature is set lower than the source material temperature, and more preferably set such that a difference between the temperatures is not smaller than 1° C. and not greater than 100° C. Further preferably, the substrate temperature is not lower than 1800° C. and not higher than 2500° C.

Referring to FIG. 12, the gas supplied as above is solidified and accordingly recrystallized on each of back surfaces B1 and B2. In this way, a supporting portion 30p connecting back surfaces B1 and B2 to each other is formed. Further, solid source material 20 (FIG. 11) is consumed and is reduced in size to be a solid source material 20p.

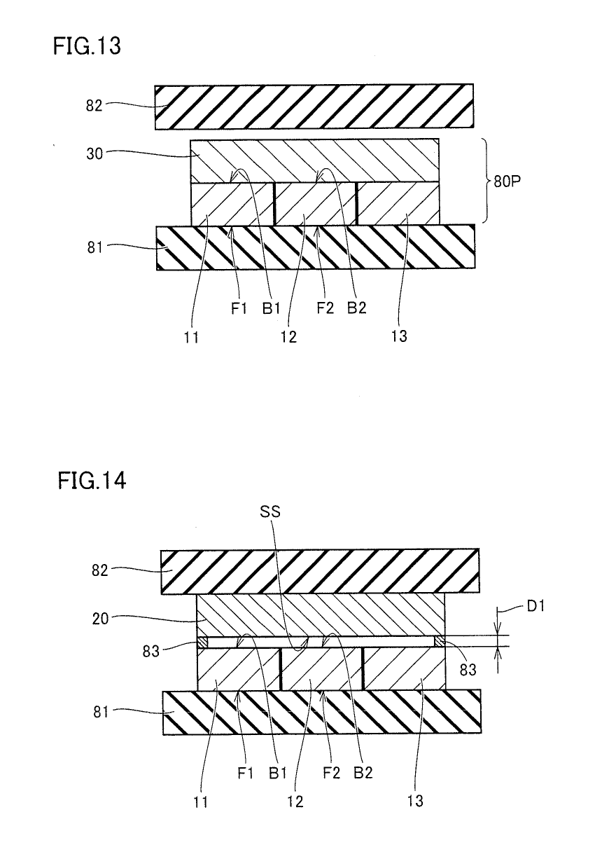

Referring mainly to FIG. 13, as sublimation further develops, solid source material 20p (FIG. 12) is run out. In this way, supporting portion 30 connecting back surfaces B1 and B2 to each other is formed.

Preferably, when supporting portion 30 is formed, an inert gas is employed as an atmosphere in the processing chamber. An exemplary inert gas that can be employed includes a noble gas such as He or Ar, a nitrogen gas, or a mixed gas of a noble gas and a nitrogen gas. When this mixed gas is used, a ratio of the nitrogen gas is set, for example, to 60%. Further, a pressure in the processing chamber is set preferably to 50 kPa or lower and more preferably to 10 kPa or lower.

Further preferably, supporting portion 30 has single crystal structure. More preferably, supporting portion 30 on back surface B1 has a crystal plane inclined by 10° or smaller relative to the crystal plane of back surface B1, or supporting portion 30 on back surface B2 has a crystal plane inclined by 10° or smaller relative to the crystal plane of back surface B2. These angular relations can readily be realized by epitaxially growing supporting portion 30 on back surfaces B1 and B2.

Crystal structure of single crystal substrate 11, 12 is preferably of hexagonal system, and more preferably 4H-SiC or 6H-SiC. Moreover, it is preferable that single crystal substrates 11, 12 and supporting portion 30 are made of SiC single crystal having the same crystal structure.

Further preferably, concentration in each of single crystal substrates 11 and 12 is different from impurity concentration in supporting portion 30. More preferably, supporting portion 30 is higher in impurity concentration than each of single crystal substrates 11 and 12. It should be noted that impurity concentration in single crystal substrate 11, 12 is, for example, not lower than 5×10¹⁶ cm⁻³ and not higher than 5×10¹⁹ cm⁻³. Further, impurity concentration in supporting portion 30 is, for example, not lower than 5×10¹⁶ cm⁻³ and not higher than 5×10²¹ cm⁻³. For example, nitrogen or phosphorus can be used as the impurity above.

Further preferably, front surface F1 has an off angle not smaller than 50° and not greater than 65° relative to the {0001} plane of single crystal substrate 11 and front surface F2 has an off angle not smaller than 50° and not greater than 65° relative to the {0001} plane of the single crystal substrate.

More preferably, an off orientation of front surface F1 forms an angle not greater than 5° relative to the <1-100> direction of single crystal substrate 11, and an off orientation of front surface F2 forms an angle not greater than 5° relative to the <1-100> direction of single crystal substrate 12.

Further preferably, front surface F1 has an off angle not smaller than −3° and not greater than 5° relative to the {03-38} plane in the <1-100> direction of single crystal substrate 11, and front surface F2 has an off angle not smaller than 31 3° and not greater than 5° relative to the {03-38} plane in the <1-100> direction of single crystal substrate 12.

It should be noted that the “off angle of front surface F1 relative to the {03-38} plane in the <1-100> direction” refers to an angle formed by an orthogonal projection of a normal line of front surface F1 to a projection plane defined by the <1-100> direction and the <0001> direction, and a normal line of the {03-38} plane. The sign of positive value corresponds to a case where the orthogonal projection approaches in parallel to the <1-100> direction whereas the sign of negative value corresponds to a case where the orthogonal projection approaches in parallel to the <0001> direction. This is also the case with the “off angle of front surface F2 relative to the {03-38} plane in the <1-100> direction.”

More preferably, an index m in a plane orientation (hklm) of front surface F1 is negative, which is also the case with front surface F2. Namely, each of front surfaces F1 and F2 is a plane close to a (000-1) plane rather than the (0001) plane.

Preferably, the off orientation of front surface F1 forms an angle not greater than 5° relative to the <11-20> direction of single crystal substrate 11, and the off orientation of front surface F2 forms an angle not greater than 5° relative to the <11-20> direction of single crystal substrate 12.

According to the present embodiment, since supporting portion 30 formed on each of back surfaces B1 and B2 is also composed of silicon carbide similarly to single crystal substrates 11 and 12, various physical properties of single crystal substrates 11 and 12 and supporting portion 30 are close to one another. Accordingly, warpage or cracks of combined substrate 80P (FIGS. 4, 5) or silicon carbide substrate 80 (FIGS. 1, 2) resulting from difference in these various physical properties can be suppressed.

Further, by using the sublimation method, supporting portion 30 can be formed fast with high quality. Furthermore, if the sublimation method is a close-spaced sublimation method in particular, supporting portion 30 can more uniformly be formed.

When the average value of distance D1 (FIG. 11) between each of back surfaces B1 and B2 and the surface of solid source material 20 is 1 cm or smaller, distribution in film thickness of supporting portion 30 can be reduced. When the average value of this distance D1 is 1 μm or greater, a space for sublimation of silicon carbide can sufficiently be secured.

In the step of forming supporting portion 30, the temperatures of single crystal substrates 11 and 12 are set lower than that of solid source material 20 (FIG. 11). Thus, sublimated SiC can efficiently be solidified on single crystal substrates 11 and 12.

Further preferably, the step of arranging single crystal substrates 11 and 12 is performed such that a shortest distance between single crystal substrates 11 and 12 is set to 1 mm or smaller. Accordingly, supporting portion 30 can be formed to more reliably connect back surface B1 of single crystal substrate 11 and back surface B2 of single crystal substrate 12 to each other.

Further preferably, supporting portion 30 has single crystal structure. Accordingly, supporting portion 30 has various physical properties close to various physical properties of each of single crystal substrates 11 and 12 similarly having single crystal structure.

More preferably, supporting portion 30 on back surface B1 has a crystal plane inclined by 10° or smaller relative to that of back surface B1. Further, supporting portion 30 on back surface B2 has a crystal plane inclined by 10° or smaller relative to that of back surface B2. Accordingly, supporting portion 30 can have anisotropy close to that of each of single crystal substrates 11 and 12.

Further preferably, each of single crystal substrates 11 and 12 is different in impurity concentration from supporting portion 30. Accordingly, silicon carbide substrate 80 (FIG. 2) having a structure of two layers different in impurity concentration can be obtained.

Further preferably, supporting portion 30 is higher in impurity concentration than each of single crystal substrates 11 and 12. Thus, supporting portion 30 can be lower in resistivity than each of single crystal substrates 11 and 12. Accordingly, silicon carbide substrate 80 suitable for manufacturing a semiconductor device in which a current flows in a thickness direction of supporting portion 30, that is, a semiconductor device of vertical type, can be obtained.

Further preferably, front surface F1 has an off angle not smaller than 50° and not greater than 65° relative to the {0001} plane of single crystal substrate 11 and front surface F2 has an off angle not smaller than 50° and not greater than 65° relative to the {0001} plane of single crystal substrate 12. Thus, channel mobility in front surfaces F1 and F2 can be enhanced as compared with a case where front surfaces F1 and F2 are the {0001} plane.

More preferably, the off orientation of front surface F1 forms an angle not greater than 5° relative to the <1-100> direction of single crystal substrate 11, and the off orientation of front surface F2 forms an angle not greater than 5° relative to the <1-100> direction of single crystal substrate 12. Thus, channel mobility in front surfaces F1 and F2 can further be enhanced.

Further preferably, front surface F1 has an off angle not smaller than −3° and not greater than 5° relative to the {03-38} plane in the <1-100> direction of single crystal substrate 11, and front surface F2 has an off angle not smaller than −3° and not greater than 5° relative to the {03-38} plane in the <1-100> direction of single crystal substrate 12. Thus, channel mobility in front surfaces F1 and F2 can further be enhanced.

Further preferably, the off orientation of front surface F1 forms an angle not greater than 5° relative to the <11-20> direction of single crystal substrate 11, and the off orientation of front surface F2 forms an angle not greater than 5° relative to the <11-20> direction of single crystal substrate 12. Thus, channel mobility in front surfaces F1 and F2 can be enhanced as compared with a case where front surfaces F1 and F2 are the {0001 } plane.

In the description above, an SiC wafer is exemplified as solid source material 20, however, solid source material 20 is not limited thereto and may be, for example, SiC powders or an SiC sintered compact.

In FIG. 11, each of back surfaces B1 and B2 and surface SS of solid source material 20 are spaced apart from each other across them, however, each of back surfaces B1 and B2 and surface SS of solid source material 20 may be spaced apart from each other while back surfaces B1 and B2 and surface SS of solid source material 20 are partially in contact with each other. Two variations corresponding to this case will be described below.

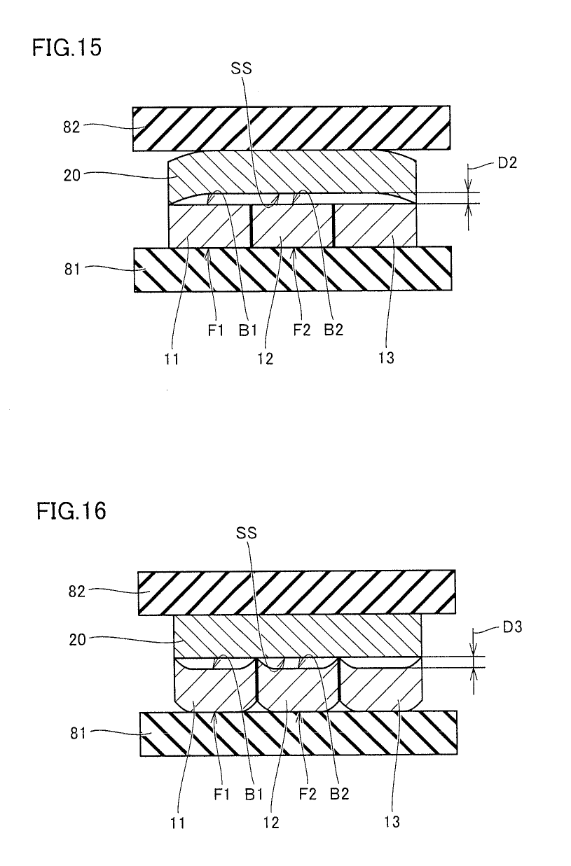

Referring to FIG. 15, in this example, the space above is secured by warpage of the SiC wafer serving as solid source material 20. More specifically, in the present example, a distance D2 is locally zero, however, an average value thereof never fails to exceed zero. Further preferably, similarly to the average value of distance D1, an average value of distance D2 is not smaller than 1 μm and not greater than 1 cm.

Referring to FIG. 16, in this example, the space above is secured by warpage of single crystal substrates 11 to 13. More specifically, in the present example, a distance D3 is locally zero, however, an average value thereof never fails to exceed zero. Further preferably, similarly to the average value of distance D1, an average value of distance D3 is not smaller than 1 μm and not greater than 1 cm.

It is noted that the space above may be secured by combination of the methods in FIG. 15 and FIG. 16, that is, by both of warpage of the SiC wafer serving as solid source material 20 and warpage of single crystal substrates 11 to 13.

The method in each of FIG. 15 and FIG. 16 or the method based on combination of these methods is particularly effective when the average value of the distance above is not greater than 100 μm.

### Third Embodiment

A method for manufacturing a silicon carbide substrate in the present embodiment and a variation thereof will be described below. For simplification of description below, only single crystal substrates 11 and 12 among single crystal substrates 11 to 19 (FIG. 1) may be mentioned, however, single crystal substrates 13 to 19 are also handled similarly to single crystal substrates 11 and 12.

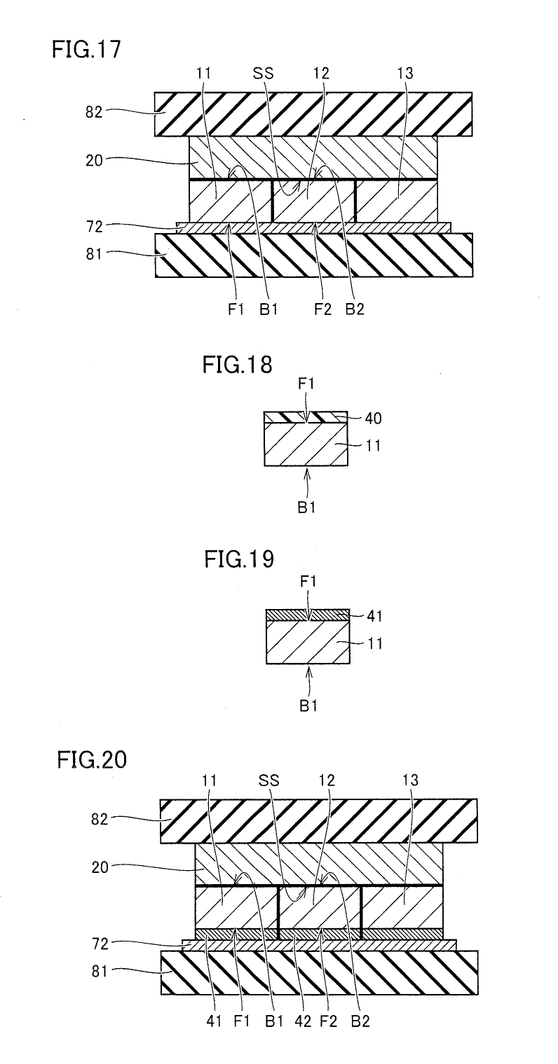

Referring to FIG. 17, in the present embodiment, graphite sheet 72 (closing portion) having flexibility is disposed on heating member 81. Then, in the processing chamber, single crystal substrates 11 and 12 are arranged on heating member 81 with graphite sheet 72 being interposed therebetween such that each of back surfaces B1 and B2 is exposed in one direction (upward in FIG. 17). Thereafter, steps similar to those in the second embodiment are performed.

Since the construction other than the above is substantially the same as the construction in the second embodiment described above, the same or corresponding elements have the same reference characters allotted and description thereof will not be repeated.

According to the present embodiment, in forming supporting portion 30 as in the second embodiment (FIG. 13), bonding portion BD (FIG. 2) is formed on graphite sheet 72 (FIG. 17). Namely, the step of forming bonding portion BD connecting side surfaces S1 and S2 to each other to thereby close opening CR of gap GP (FIG. 7) is performed simultaneously with the step of bonding each of back surfaces B1 and B2 to supporting portion 30 (FIG. 13). Hence, the steps can be simplified as compared with a case of separately performing the step of forming bonding portion BD and the step of bonding each of back surfaces B1 and B2.

Further, since graphite sheet 72 has flexibility, gap GP (FIG. 7) can more reliably be closed. Therefore, as a plane where bonding portion BD should grow, a plane implemented by graphite sheet 72 can reliably be provided as the plane other than single crystal substrates 11 and 12. Thus, at least a part of bonding portion BD can readily be formed from polycrystalline portion BDb while formation of bonding portion BD formed only from single crystal portion BDa is avoided.

A variation of the present embodiment will now be described.

Referring to FIG. 18, a resist liquid 40 is applied onto front surface F1 of single crystal substrate 11. Then, resist liquid 40 is carbonized.

Referring to FIG. 19, by carbonization above, a protective film 41 covering front surface F1 of single crystal substrate 11 is formed. A protective film covering front surface F2 of single crystal substrate 12 is also similarly formed.

Referring to FIG. 20, as in the present embodiment, single crystal substrates 11 and 12 are arranged on heating member 81 with graphite sheet 72 being interposed therebetween. In the present variation, however, by this time point of arrangement, protective film 41 has been formed on front surface F1 facing graphite sheet 72. In addition, protective film 42 similar to protective film 41 has been formed on front surface F2 facing graphite sheet 72.

According to the present variation, in forming bonding portion BD described above on graphite sheet 72, protective films 41 and 42 serve to avoid sublimation/resolidification on front surfaces F1 and F2. Accordingly, front surfaces F1, F2 can be prevented from being roughened.

In addition, gap GP (FIG. 7) is extended by protective films 41 and 42, and a part of the side surface of this extended gap is formed of a material for protective films 41 and 42, that is, a material different from single crystal silicon carbide. Bonding portion BD grown on the side surface made of a material for protective films 41 and 42 is more likely to become polycrystalline portion BDb (FIG. 3B) rather than single crystal portion BDa (FIG. 3A). Thus, polycrystalline portion BDb can more reliably be provided.

### Fourth Embodiment

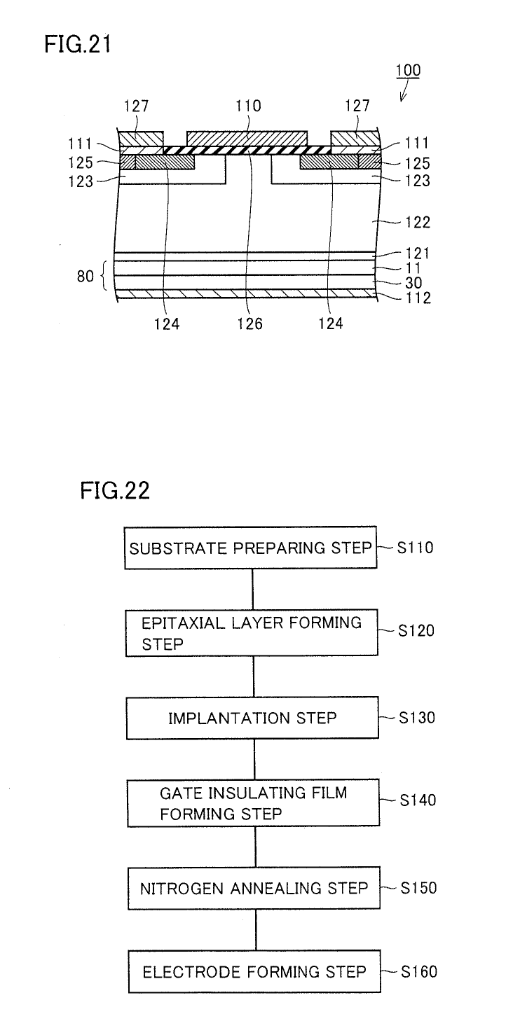

Referring to FIG. 21, a semiconductor device 100 in the present embodiment is a vertical DiMOSFET (Double Implanted Metal Oxide Semiconductor Field Effect Transistor), and it has silicon carbide substrate 80, a buffer layer 121, a reverse breakdown voltage holding layer 122, a p region 123, an n⁺ region 124, a p⁺ region 125, an oxide film 126, a source electrode 111, an upper source electrode 127, a gate electrode 110, and a drain electrode 112.

In the present embodiment, silicon carbide substrate 80 has an n conductivity type, and has supporting portion 30 and single crystal substrate 11 as described in the first embodiment. Drain electrode 112 is provided on supporting portion 30 such that supporting portion 30 lies between drain electrode 112 and single crystal substrate 11. Buffer layer 121 is provided on single crystal substrate 11 such that single crystal substrate 11 lies between buffer layer 121 and supporting portion 30.

Buffer layer 121 has an n conductivity type, and has a thickness, for example, of 0.5 μm. Further, concentration of an n-type conductive impurity in buffer layer 121 is, for example, 5×10¹⁷ cm⁻³.

Reverse breakdown voltage holding layer 122 is formed on buffer layer 121, and made of silicon carbide having an n conductivity type. For example, reverse breakdown voltage holding layer 122 has a thickness of 10 μm, and concentration of an n-type conductive impurity therein is 5×10¹⁵ cm⁻³.

In the surface of this reverse breakdown voltage holding layer 122, a plurality of p regions 123 having a p conductivity type are formed at a distance from each other. In p region 123, n⁺ region 124 is formed in a surface layer of p region 123. Further, at a position adjacent to this n⁺ region 124, p⁺ region 125 is formed. Oxide film 126 is formed to extend from n⁺ region 124 in one p region 123 over p region 123, reverse breakdown voltage holding layer 122 exposed between two p regions 123, and the other p region 123 to n⁺ region 124 in the other p region 123. On oxide film 126, gate electrode 110 is formed. Further, source electrode 111 is formed on n⁺ region 124 and p⁺ region 125. On source electrode 111, upper source electrode 127 is formed.

A maximum value of concentration of nitrogen atoms is not lower than 1×10²¹ cm⁻³ in a region within 10 nm from an interface between oxide film 126 and each of n⁺ region 124, p⁺ region 125, p region 123, and reverse breakdown voltage holding layer 122 serving as semiconductor layers. Thus, mobility particularly in a channel region below oxide film 126 (a portion of p region 123 between n⁺ region 124 and reverse breakdown voltage holding layer 122, in contact with oxide film 126) can be improved.

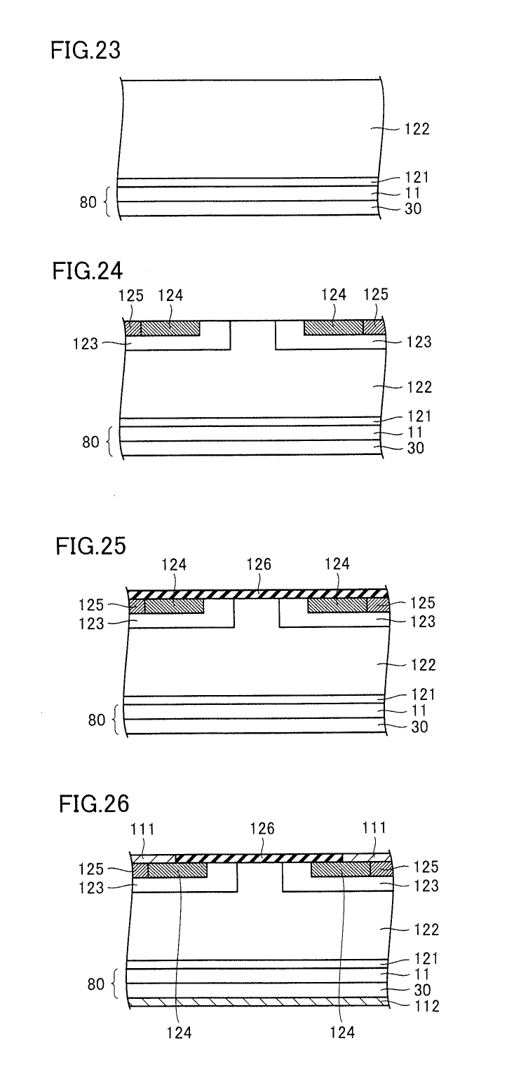

A method for manufacturing semiconductor device 100 will now be described. It should be noted that FIGS. 23 to 26 show only steps in the vicinity of single crystal substrate 11 among single crystal substrates 11 to 19 (FIG. 1), however, similar steps are performed also in the vicinity of each of single crystal substrate 12 to single crystal substrate 19.

Initially, in a substrate preparing step (step S110: FIG. 22), silicon carbide substrate 80 (FIGS. 1 and 2) is prepared. Silicon carbide substrate 80 has an n conductivity type.

Referring to FIG. 23, in an epitaxial layer forming step (step S120: FIG. 22), buffer layer 121 and reverse breakdown voltage holding layer 122 are formed as follows.

Initially, buffer layer 121 is formed on the surface of silicon carbide substrate 80. Buffer layer 121 is composed of silicon carbide having an n conductivity type, and it is an epitaxial layer having a thickness, for example, of 0.5 μm. Concentration of a conductive impurity in buffer layer 121 is, for example, 5×10¹⁷ cm⁻³.

Then, reverse breakdown voltage holding layer 122 is formed on buffer layer 121. Specifically, a layer composed of silicon carbide having an n conductivity type is formed with an epitaxial growth method. Reverse breakdown voltage holding layer 122 has a thickness, for example, of 10 μm. Concentration of an n-type conductive impurity in reverse breakdown voltage holding layer 122 is, for example, 5×10¹⁵ cm ⁻³.

Referring to FIG. 24, in an implantation step (step S 130: FIG. 22), p region 123, n⁺ region 124, and p⁺ region 125 are formed as follows.

Initially, an impurity having a p conductivity type is selectively implanted into a part of reverse breakdown voltage holding layer 122, to thereby form p region 123. Then, an n-type conductive impurity is selectively implanted into a prescribed region to thereby form n⁺ region 124, and a conductive impurity having a p conductivity type is selectively implanted into a prescribed region to thereby form p⁺ region 125. It should be noted that such selective implantation of impurities is performed using a mask formed, for example, from an oxide film.

After such an implantation step, activation annealing treatment is performed. For example, annealing is performed in an argon atmosphere at a heating temperature of 1700° C. for 30 minutes.

Referring to FIG. 25, a gate insulating film forming step (step S140: FIG. 22) is performed. Specifically, oxide film 126 is formed to cover reverse breakdown voltage holding layer 122, p region 123, n⁺ region 124, and p⁺ region 125. Formation may be achieved through dry oxidation (thermal oxidation). Conditions for dry oxidation are, for example, such that a heating temperature is set to 1200° C. and a heating time period is set to 30 minutes.

Thereafter, a nitrogen annealing step (step S150) is performed. Specifically, annealing treatment is performed in a nitrogen monoxide (NO) atmosphere. Conditions for this treatment are, for example, such that a heating temperature is set to 1100° C. and a heating time period is set to 120 minutes. As a result, nitrogen atoms are introduced in the vicinity of the interface between oxide film 126 and each of reverse breakdown voltage holding layer 122, p region 123, n⁺ region 124, and p⁺ region 125.

It should be noted that, after this annealing step using nitrogen monoxide, annealing treatment using an argon (Ar) gas representing an inert gas may further be performed. Conditions for this treatment are, for example, such that a heating temperature is set to 1100° C. and a heating time period is set to 60 minutes.

Referring to FIG. 26, in an electrode forming step (step S160: FIG. 22), source electrode 111 and drain electrode 112 are formed in the following manner.

Initially, a resist film having a pattern is formed on oxide film 126 with a photolithography method. Using this resist film as a mask, a portion of oxide film 126 located on n⁺ region 124 and p⁺ region 125 is etched away. In this way, an opening is formed in oxide film 126. Then, in the opening, a conductor film is formed in contact with each of n⁺ region 124 and p⁺ region 125. Then, the resist film is removed, to thereby remove the portion of the conductor film located on the resist film (lift-off). This conductor film may be a metal film, and for example, it may be made of nickel (Ni). As a result of lift-off, source electrode 111 is formed.

It should be noted that heat treatment for alloying is preferably performed here. For example, heat treatment is performed in an atmosphere of an argon (Ar) gas, which is an inert gas, at a heating temperature of 950° C. for two minutes.

Referring again to FIG. 21, upper source electrode 127 is formed on source electrode 111. Further, drain electrode 112 is formed on the back surface of silicon carbide substrate 80. Semiconductor device 100 is obtained as above.

It is noted that a configuration in which conductivity types are interchanged in the present embodiment, that is, a configuration in which p-type and n-type are interchanged, may also be employed.

Further, a silicon carbide substrate for fabricating semiconductor device 100 is not limited to silicon carbide substrate 80 in the first embodiment, and may be, for example, the silicon carbide substrate in the second or third embodiment or the silicon carbide substrate in the variation of each embodiment.

Further, though the vertical DiMOSFET has been exemplified, another semiconductor device may be manufactured using the silicon carbide substrate according to the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate, comprising:
a first single crystal substrate having a first side surface and composed of silicon carbide;
a second single crystal substrate having a second side surface opposed to said first side surface and composed of silicon carbide; and
a bonding portion connecting said first and second side surfaces to each other between said first and second side surfaces and composed of silicon carbide, at least a part of said bonding portion having polycrystalline structure.

2. The silicon carbide substrate according to claim 1, wherein
said first and second single crystal substrates have first and second back surfaces, respectively, and
said silicon carbide substrate further comprises a supporting portion bonded to each of said first and second back surfaces.

3. The silicon carbide substrate according to claim 1, wherein
said first and second single crystal substrates have first and second front surfaces, respectively, and
said bonding portion is formed to linearly extend between said first and second front surfaces in a plan view and a length of a portion of said bonding portion having polycrystalline structure in a direction of linear extension is not less than 1% and not more than 100% of an entire length of said bonding portion.

4. The silicon carbide substrate according to claim 3, wherein
the length of the portion of said bonding portion having polycrystalline structure in said direction of linear extension is not less than 10% of the entire length of said bonding portion.

5. The silicon carbide substrate according to claim 1, wherein
a ratio of a maximum length in the plan view of said silicon carbide substrate with respect to a thickness of said silicon carbide substrate is not lower than 50 and not higher than 500.

6. The silicon carbide substrate according to claim 1, wherein
a maximum length in a plan view of said silicon carbide substrate is not smaller than 100 mm.
